(19) United States
(12) Patent Application Publication
(10) Pub. No.: US 2021/0259131 A1
(43) Pub. Date: Aug. 19, 2021

(54) ELECTRONIC DEVICE

(71) Applicant: SHARP KABUSHIKI KAISHA, Sakai City (JP)

(72) Inventors: TOMOYA IDE, Sakai City (JP); KOHJI SAWAYAMA, Sakai City (JP); HIROKI TANABE, Sakai City (JP)

(21) Appl. No.: 17/174,630

(22) Filed: Feb. 12, 2021

(30) Foreign Application Priority Data
Feb. 14, 2020 (JP) 2020-023826

(51) Int. Cl. H05K 7/20; H04M 1/02

(52) U.S. Cl. CPC H05K 7/2039; H04M 1/026

(57) ABSTRACT

An electronic device comprises a plurality of electronic components that are heat-generating bodies; a heat radiation member; and a plurality of heat paths through which heat is conducted from the plurality of electronic components to the heat radiation member and at least one of which is provided with a heat storage member that increases heat capacity of the heat path.

### BACKGROUND

### 1. Field

An aspect of the present disclosure relates to an electronic device that includes a plurality of electronic components.

### 2. Description of the Related Art

In general, it is desirable that electronic devices operate at a temperature within a set temperature range. It is therefore desirable that heat generated by operation of an electronic component provided in the electronic devices is promptly conducted to a heat radiation member and radiated to the outside from the heat radiation member.

For example, an electronic control unit described in Japanese Unexamined Patent Application Publication No. 2003-289191 includes a thermally conductive material between a side of a printed circuit board, which is opposite to a place where an electronic component is mounted, and a protrusion of a cover. Thus, the electronic control unit is able to radiate heat generated in the electronic component to the outside through the printed circuit board, the thermally conductive material, and the protrusion of the cover.

A typical electronic device includes a plurality of electronic components that can be a plurality of heat sources (heat-generating bodies). When heat from the plurality of electronic components is conducted to a heat radiation member all at once, the amount of heat flowing into the heat radiation member is larger than the amount of heat flowing out of the heat radiation member, and temperature of the heat radiation member may rise. At this time, temperature of a certain electronic component may rise and exceed the set temperature range.

An aspect of the disclosure realizes an electronic device that is able to promptly conduct heat from a certain electronic component to a heat radiation member.

### SUMMARY

An electronic device according to an aspect of the disclosure includes: a plurality of electronic components that are heat-generating bodies; a heat radiation member; and a plurality of heat paths through which heat is conducted from the plurality of electronic components to the heat radiation member and at least one of which is provided with a heat storage member that increases heat capacity of the heat path.

### BRIEF DESCRIPTION OF THE DRAWINGS

FIG. 1 is a sectional view illustrating a portion of an electronic device according to an embodiment of the disclosure;

FIG. 2 illustrates graphs of a case where a portable terminal for 5G which is an exemplary embodiment of the electronic device performs data communication with a base station;

FIG. 3 is a sectional view illustrating a portion of an electronic device according to another embodiment of the disclosure; and

FIG. 4 is a sectional view illustrating a portion of an electronic device according to still another embodiment of the disclosure.

### DESCRIPTION OF THE EMBODIMENTS

Embodiments of the disclosure will be described below in detail. Note that, for convenience of description, members having the same functions as those of members described in Embodiments will be given the same reference numerals, and description thereof will be omitted.

### Embodiment 1

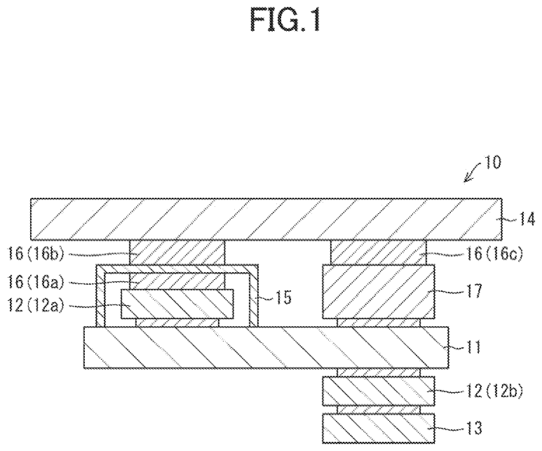

An embodiment of the disclosure will be described with reference to FIG. 1.

### Configuration of Electronic Device

FIG. 1 is a sectional view illustrating a portion of an electronic device according to the present embodiment. The electronic device includes a plurality of electronic components. Examples of the electronic device include a portable terminal and a PC (personal computer), and the electronic device is not limited thereto.

As illustrated in FIG. 1, an electronic device 10 includes a printed circuit board 11, electronic components 12 (12a and 12b), an electronic component 13, a heat radiation plate 14 (heat radiation member), a metal shield 15, TIMs (thermal interface materials) 16 (16a to 16c), and a metal block 17 (metal member).

The plurality of electronic components 12 and 13 are mounted on surfaces of the printed circuit board 11. In the example of FIG. 1, the electronic component 12a is mounted on a surface (facing surface) of the printed circuit board 11, which faces the heat radiation plate 14, and the electronic components 12b and 13 are PoP (package on package) mounted on a surface (opposite surface) opposite to the facing surface.

The electronic component 12 consumes a relatively large amount of power when operating and therefore serves as a heat source (heat-generating body) heat of which is to be conducted to the heat radiation plate 14. Examples of the electronic component 12 include a processor and an IC (integrated circuit) such as a power amplifier. The electronic component 13 consumes a relatively small amount of power when operating, and heat thereof is thus not required to be conducted to the heat radiation plate 14. Examples of the electronic component 13 include an IC such as memory.

The heat radiation plate 14 radiates, to the outside, the teat conducted from the heat source. The heat radiation plate 14 is a plate member which is formed of metal having low thermal resistance. Note that the heat radiation plate 14 may be a member of any shape, such as a heat sink.

In the present embodiment, the TIM 16a, the metal shield 15, and the TIM 16b are provided between the electronic component 12a (certain electronic component) and the heat radiation plate 14, and these members constitute a heat path (first heat path) from the electronic component 12a to the heat radiation plate 14. On the other hand, the printed circuit board 11, the metal block 17, and the TIM 16c are provided between the electronic component 12b (different electronic component) and the heat radiation plate 14, and these members constitute a heat path (second heat path) from the electronic component 12b to the heat radiation plate 14.

The metal shield 15 protects the exterior of the electronic component 12a from electromagnetic waves and is provided so as to cover the electronic component 12a. Stainless steel is typically used for the metal shield 15.

The TIM 16 is also referred to as a thermally conductive material and is used for filling a space generated between the electronic component 12 and the heat radiation plate 14 to efficiently conduct heat from the electronic component 12 to the heat radiation plate 14. The TIM 16 is desired to have high thermal conductivity, plasticity, and electrical insulation properties. For example, the thermally conductive material which is flexible and semi-solid is used in Japanese Unexamined Patent Application Publication No. 2003-289191, and a silicon-type gel resin material containing a metal is cited as an example of the thermally conductive material.

The metal block 17 is a heat storage member that increases heat capacity in the neat path. The metal block 17 is mounted by soldering on a side of the printed circuit board 11, which is opposite to the electronic component 12b, that is, on the heat radiation plate 14 side. A space between the metal block 17 and the heat radiation plate 14 is filled with the TIM 16c.

The metal block 17 may be formed of copper, nickel, alumina (aluminum oxide), or an alloy of at least two of them. Note that copper, nickel, and alumina have heat capacity of 3.44 [J/K], 4.09 [J/K], and 3.04 [J/K] per 1 cm³, respectively. Moreover, the metal block 17 is desired to be solid, but is not limited thereto, and may be, for example, porous.

According to the aforementioned configuration, in the second heat path in which the metal block 17 is provided, an increase in heat capacity results in an increase in time constant. Accordingly, it is possible to easily make the time constant of the first heat path and the time constant of the second heat path different. Thereby, the time constant of the second heat path from the electronic component 12b to the heat radiation plate 14 is made larger than the time constant of the first heat path from the electronic component 12a to the heat radiation plate 14, and therefore a flow of the heat from the electronic component 12b to the heat radiation plate 14 is able no be made gentle. Consequently, it is possible to promptly conduct the heat from the electronic component 12a to the heat radiation plate 14 and to reduce the possibility of temperature of the electronic component 12a rising and exceeding a set temperature range. Moreover, it is possible to suppress a rise in temperature of the heat radiation plate 14.

In addition, since the metal block 17 has relatively low thermal resistance, it is possible to suppress an increase in temperature difference between the electronic component 12b and the heat radiation plate 14 between which the second heat path in which the metal block 17 is provided lies.

Note that the electronic component 12a (first electronic component) may intermittently operate, the electronic component 12b (second electronic component) may continuously operate, and power consumption of the electronic component 12a may be larger than that of the electronic component 12b. In this case, a temperature change of the electronic component 12a is greater than that of the electronic component 12b. Thus, by making the time constant of the second heat path from the electronic component 12b to the heat radiation plate 14 larger than the time constant of the first heat path from the electronic component 12a to the heat radiation plate 14, it is possible to promptly conduct the heat from the electronic component 12a to the heat radiation plate 14. As a result, it is possible to effectively suppress a rise in temperature or the electronic component 12a and also to effectively suppress a rise in temperature of the heat radiation plate 14.

### Exemplary Embodiment

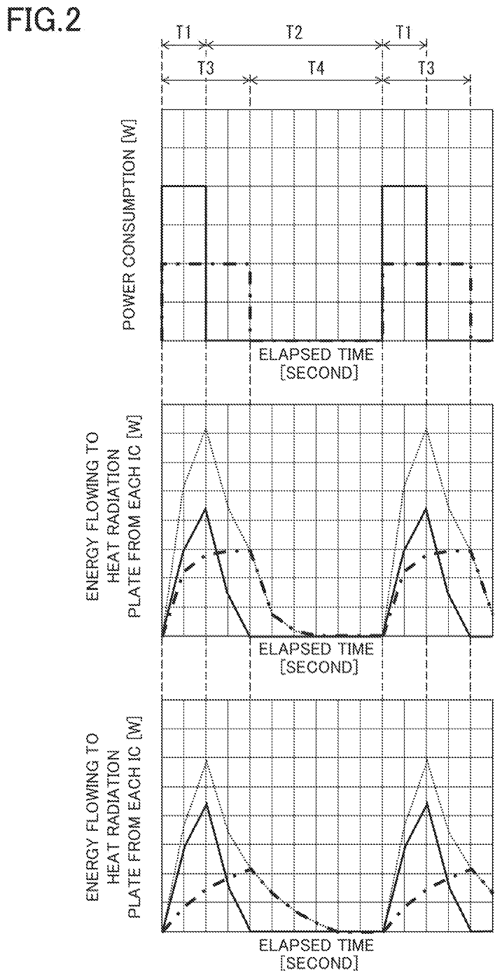

Next, an exemplary embodiment of the present embodiment will be described with reference to FIG. 2.

In the present exemplary embodiment, the electronic device 10 is a portable terminal for Fifth Generation (5G) mobile communication system. Moreover, the electronic component 12a is a 5G modem (IC for wireless communication) that executes a communication operation for 5G, and the electronic component 12b is a CPU (central processing unit) (IC for control) that executes a processing operation of data such as data for communication. Note that examples of the portable terminal 10 include a smartphone and a tablet terminal, but there is no limitation thereto.

In the portable terminal for 5G, the 5G modem 12a spends short time for operating but consumes a large amount of power compared with the CPU 12b.

Then, in the present exemplary embodiment, while the metal block 17 is omitted in the first heat path from the 5G modem 12a to the heat radiation plate 14, the metal block 17 is provided in the second heat path from the CPU 12b to the heat radiation plate 14. In this case, the time constant of the first heat path is able to be made smaller than that of the second heat path. Accordingly, when the 5G modem 12a and the CPU 12b simultaneously operate and simultaneously rise in temperature, it is possible to promptly conduct heat from the 5G modem 12a to the heat radiation plate 14 through the first heat path having the small time constant. Consequently, it is possible to effectively suppress a rise in temperature of the 5G modem 12a. On the other hand, a rise in temperature of the heat radiation plate 14 which is caused by the CPU 12b is gentle. As a result, it is possible to effectively suppress the rise in temperature of the heat radiation plate 14.

FIG. 2 illustrates graphs of a case where the portable terminal for 5G performs data communication with a base station. The upper graph illustrates a change with time of power consumption of the 5G modem 12a and the CPU 12b. The middle and lower graphs illustrate a change with time of heat energy flowing from the 5G modem 12a and the CPU 12b to the heat radiation plate 14. In FIG. 2, the graphs regarding the 5G modem 12a are indicated with solid lines, and the graphs regarding the CPU 12b are indicated with one-dot chain lines. Moreover, in the middle and lower graphs of FIG. 2, a graph integrating the graph of the solid line and the graph of the one-dot chain line is indicated with a broken line.

Moreover, the lower graph of FIG. 2 is a graph regarding the portable terminal 10 of the present exemplary embodiment. On the other hand, the middle graph of FIG. 2 is a reference example and is a graph regarding a configuration in which a TIM is substituted for the metal block 17 in the portable terminal 10 of the present exemplary embodiment. Thermal resistance of the TIM is as small as that of the metal block 17 from the viewpoint of heat radiation. On the other hand, differently from the metal block 17, heat capacity of the TIM is small.

In FIG. 2, time T1 is a time during which the 5G modem 12a executes the communication operation, and time T2 is a time during which the 5G modem 12a stops the execution of the communication operation. Moreover, time T3 is a time during which the CPU 12b executes the processing operation of data regarding data communication, and time T4 is a time during which the CPU 12b stops the execution of the processing operation of the data regarding data communication. Note that lengths, start timings, and end timings of time T1 and time T3 may be freely set as long as at least time T1 and time T3 partially overlap.

With reference to FIG. 2, the 5G modem 12a consumes a large amount of power compared with other electronic components including the CPU 12b in time T1. Thus, a rise in temperature of the 5G modem 12a in time T1 becomes a problem. The temperature of the 5G modem 12a is expressed by the following expression (1).

(temperature of 5G modem 12a)=(temperature of heat radiation plate 14)+(thermal resistance of first heat path)×(heat energy from 5G modem 12a to heat radiation plate 14 per unit time) (1)

With reference to the expression (1), to keep the temperature of the 5G modem 12a low for a longer time, it is understood that the thermal resistance [K/W] of the first heat path may be made as small as possible. Then, in the present exemplary embodiment, a space between the 5G modem 12a and the metal shield 15 is filled with the TIM 16a such that no gap is generated therebetween. Furthermore, a space between the metal shield 15 and the heat radiation plate 14 is filled with the TIM 16b such that no gap is generated therebetween. Note that another electronic component between the 5G modem 12a and the heat radiation plate 14 is not desired to be provided, since the thermal resistance or the first heat path increases.

Moreover, with reference to the expression (1), to keep the temperature of the 5G modem 12a low for a longer time, it is understood that a flow of heat other than the heat from the 5G modem 12a to the heat radiation plate 14 may be suppressed in time T1 to keep the temperature of the heat radiation plate 14 low. Thus, in the present exemplary embodiment, the metal block 17 that increases heat capacity is provided in the second heat path. When the graphs of the one-dot chain lines in the middle and lower graphs of FIG. 2 are compared, it is understood that a flow of heat energy from the second heat path to the heat radiation plate 14 is gentler in a case where the metal block 17 is provided than in a case where the metal block 17 is not provided.

When the graphs of the broken lines in the middle and lower graphs of FIG. 2 are compared, it is understood that a maximum value of a sum of heat energy flowing to the heat radiation plate 14 is suppressed in the case where the metal block 17 is provided more than in the case where the metal block 17 is not provided. That is, it is possible to keep the temperature of the heat radiation plate 14 low.

Next, description will be given for the flow of the heat energy from the second heat path to the heat radiation plate 14, which is made gentle by an increase in heat capacity of the second heat path.

When thermal resistance of the second heat path is R and the quantity of heat flow thereof is Q, a temperature difference ΔT of the second heat path is expressed by the following expression (2).

ΔT=R×Q(1−exp(−t/τ)) (2)

where τ denotes the time constant, and t denotes an elapsed time.

According to the expression (2), a maximum temperature difference ΔTmax is expressed by the following expression (3).

ΔTmax=R×Q (3)

Moreover, the time constant τ indicates a time in which ΔT reaches 63.2% of ΔTmax from 0. According to the expression (2), it is understood that the larger the time constant τ is, the longer the time (saturation time) in which ΔT reaches ΔTmax from 0 is. The time constant τ is expressed by the following expression (4):

τ=R×C (4)

where the heat capacity in the second heat path is C.

As above, by increasing the heat capacity C of the second heat path, it is possible to increase the time constant τ, and it is consequently possible to make the saturation time longer. That is, it is possible to make the flow of the heat energy from the second heat path to the heat radiation plate 14 gentle.

For example, regarding the second heat path, it is assumed that the thermal resistance R is 15 [K/W], the quantity of heat flow Q is 1 [W], and saturation temperature is 15[°C]. In this case, when the heat capacity C is 1 [J/K], the time constant is 15 [s], and the saturation time is 121 [s]. On the other hand, when the heat capacity C is 1.2 [J/K], the time constant is 18 [s], and the saturation time is 145 [s]. Thus, simply by increasing the heat capacity C by 0.2 [J/K], it is possible to increase the saturation time by 24 [s].

### Additional Notes

Note that, although the electronic components 12a and 12b are mounted on the surfaces of the printed circuit board 11 in the present embodiment, the electronic components 12a and 12b may be mounted on one surface of the printed circuit board 11. In this case, the second heat path from the electronic component 12b to the heat radiation plate 14 is constituted by the metal block 17 and the TIM 16c.

Moreover, although the electronic components 12a and 12b are mounted on one printed circuit board 11 in the present embodiment, the electronic components 12a and 12b may be mounted on separate printed circuit boards.

### Embodiment 2

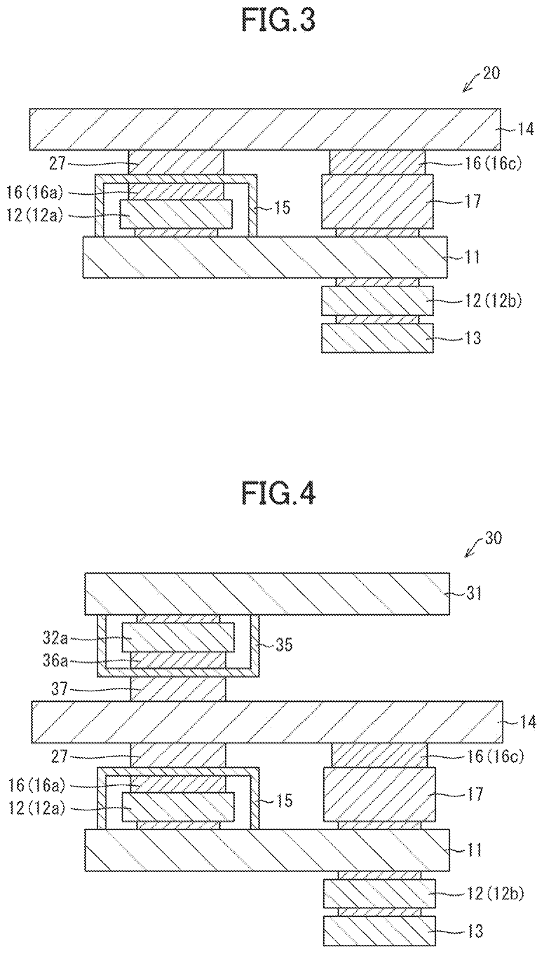

Another embodiment of the disclosure will be described with reference to FIG. 3.

FIG. 3 is a sectional view illustrating a portion of an electronic device according to the present embodiment. An electronic device 20 of the present embodiment differs from the electronic device 10 illustrated in FIG. 1 in that a metal block 27 is provided instead of the TIM 16b, and is similar thereto in other configurations.

The metal block 27 is a heat storage member that increases heat capacity in a heat path similarly to the metal block 17. A metal block may be provided in each of the plurality of heat paths as long as a change in heat capacity of the plurality of heat paths enables the time constants of the plurality of heat paths to differ from each other as described above.

### Embodiment 3

Still another embodiment of the disclosure will be described with reference to FIG. 4.

FIG. 4 is a sectional view illustrating a portion of an electronic device according to the present embodiment. An electronic device 30 of the present embodiment differs from the electronic device 20 illustrated in FIG. 3 in that a printed circuit board 31, an electronic component 32a, a TIM 36a, a metal shield 35, and a metal block 37 which are similar to the printed circuit board 11, the electronic component 12a, the TIM 16a, the metal shield 15, and the TIM 16b are additionally provided on the other side of the heat radiation plate 14, and is similar thereto in other configurations.

As above, the electronic component 12 serving as a heat source may be provided on both sides of the heat radiation plate 14. When the metal blocks 27, 17, and 37 are provided in three heat paths from the electronic components 12a, 12b, and 32a to the heat radiation plate 14 to thereby adult the time constants τ in the three heat paths, an effect similar to those of the aforementioned embodiments is able to be exerted.

For example, the electronic components 12a, 12b, and 32a are assumed to be the 5G modem 12a, the CPU 12b, and a power amplifier for communication 32a, respectively. In a case where priority of heat radiation is assigned to the power amplifier for communication 32a, the 5G modem 12a, and the CPU 12b in this order, it is sufficient that the metal blocks 37, 27, and 17 provided in the three heat paths be adjusted such that the ascending order of the time constants τ is the electronic components 32a, 12a, and 12b. Note that the priority of heat radiation depends on design.

### Additional Notes

Note that, although the metal block is used for the heat storage member in the embodiments, any heat storage member such as ceramics or a latent heat storage material heat storage performance of which appears at a phase change point (temperature of the phase change) is able to be used. However, from the viewpoint of heat radiation, a heat storage member having small thermal resistance, such as a metal block, is desired to be used.

Moreover, although heat radiation from the electronic components 12 to the heat radiation 14 is described in the embodiments, heat radiation from the electronic components 12 is desired to be collectively performed, for example, by performing not only the heat radiation from the electronic components 12 to the heat radiation 14 but also heat radiation by using the metal shield 15 or heat radiation by using a connection member between the printed circuit board 11 and the heat radiation plate 14.

### Conclusion

An electronic device according to an aspect 1 of the disclosure includes: a plurality of electronic components that are heat-generating bodies; a heat radiation member; and a plurality of heat paths through which heat is conducted from the plurality of electronic components to the heat radiation member and at least one of which is provided with a heat storage member that increases heat capacity of the heat path.

In the aforementioned configuration, the heat path provided with the heat storage member has the increased heat capacity, and the time constant thereof thus increases. Accordingly, it is possible to easily differentiate the time constants of the plurality of heat paths. Therefore, when, compared with a time constant of a heat path from a certain electronic component to the heat radiation member, a time constant of a heat path from a different electronic component to the heat radiation member is made large, it is possible to make a flow of heat from the different electronic component to the heat radiation member gentle. Consequently, heat from the certain electronic component to the heat radiation member is able to be promptly conducted, and it is possible to reduce the possibility of temperature of the certain electronic component rising and exceeding a set temperature range.

In the electronic device according to an aspect 2 of the disclosure, the heat storage member may be a metal member in the aspect 1. In this case, since the metal member has relatively low thermal resistance, it is possible to suppress an increase in temperature difference between the electronic component and the heat radiation member between which the heat path in which the metal member is provided lies.

In the electronic device according to an aspect 3 of the disclosure, the plurality of electronic components may include a first electronic component that intermittently operates and a second electronic component that continuously operates, and the first electronic component may consume a large amount of power compared with the second electronic component, in the aspect 1 or 2. In this case, a temperature change of the first electronic component is greater than that of the second electronic component. Therefore, when a time constant of a heat path from the second electronic component to the heat radiation member is made larger than a time constant of a heat path from the first electronic component to the heat radiation member, it is possible to promptly conduct heat from the first electronic component to the heat radiation member. Consequently, it is possible to effectively suppress a rise in temperature of the first electronic component.

In the electronic device according to an aspect 4 of the disclosure, the first electronic component may be an IC (integrated circuit) for wireless communication, and the second electronic component may be an IC for control, in the aspect 3.

By the way, in a recent Fifth Generation cellular phone, an IC for wireless communication spends short time for operating but consumes a large amount of power compared with an IC for control.

Then, in the electronic device according to an aspect 5 of the disclosure, the heat storage member may be omitted in the heat path from the IC for wireless communication to the heat radiation member, and the heat storage member may be provided in the heat path from the IC for control to the heat radiation member, in the aspect 4.

In this case, the time constant of the heat path from the IC for wireless communication to the heat radiation member is able to be made smaller than that of the heat path from the IC for control to the heat radiation member. Accordingly, when the IC for wireless communication and the IC for control simultaneously operate and simultaneously rise in temperature, it is possible to promptly conduct heat from the IC for wireless communication to the heat radiation member through the heat path having the small time constant. Consequently, it is possible to effectively suppress a rise in temperature of the IC for wireless communication. Or the other hand, a rise in temperature of the heat radiation member which is caused by the IC for control is gentle. As a result, it is possible to effectively suppress a rise in temperature of the heat radiation member.

The disclosure is not limited to each of the embodiments described above and may be modified in various manners within the scope indicated in the Claims, and an embodiment achieved by appropriately combining techniques disclosed in each of different embodiments is also encompassed in the technical scope of the disclosure. Further, by combining the techniques disclosed in each of the embodiments, a new technical feature may be formed.

The present disclosure contains subject matter related to that disclosed in Japanese Priority Patent Application JP 2020-023826 filed in the Japan Patent Office on Feb. 14, 2020, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic device comprising:
a plurality of electronic components that are heat-generating bodies;
a heat radiation member; and
a plurality of heat paths through which heat is conducted from the plurality of electronic components to the heat radiation member and at least one of which is provided with a heat storage member that increases heat capacity of the heat path.

2. The electronic device according to claim 1, wherein the heat storage member is a metal member.

3. The electronic device according to claim 1, wherein the plurality of electronic components include a first electronic component that intermittently operates and a second electronic component that continuously operates, and the first electronic component consumes a large amount of power compared with the second electronic component.

4. The electronic device according to claim 3, wherein the first electronic component is an integrated circuit for wireless communication, and the second electronic component is an integrated circuit for control.

5. The electronic device according to claim 4, wherein
the heat storage member is omitted in the heat path from the integrated circuit for wireless communication to the heat radiation member, and
the heat storage member is provided in the heat path from the integrated circuit for control to the heat radiation member.
